(19) United States
(12) Patent Application Publication
(10) Pub. No.: US 2025/0069987 A1
(43) Pub. Date: Feb. 27, 2025

(54) A THERMAL INTERFACE MATERIAL, AN INTEGRATED CIRCUIT ASSEMBLY, AND A METHOD FOR THERMALLY CONNECTING LAYERS

(71) Applicant: Arieca Inc., Pittsburgh, PA (US)

(72) Inventors: Navid Kazem, Pittsburgh, PA (US); Carmel Majidi, Pittsburgh, PA (US); Jeffrey Gelorme, Burlington, CT (US); Vivek Singh, Pittsburgh, PA (US)

(21) Appl. No.: 18/729,393

(22) PCT Filed: Feb. 13, 2023
(86) PCT No.: PCT/US2023/062459

§ 371 Date: Jul. 16, 2024

Related U.S. Application Data
(60) Provisional application No. 63/268,134, filed on Feb. 17, 2022.

(51) Int. Cl. H01L 23/373; C09J 11/04; C09J 183/06; H01L 23/00

(52) U.S. Cl. CPC H01L 23/3737; C09J 11/04; C09J 183/06; H01L 24/29; H01L 24/83; C09J 2483/00; H01L 2224/2929; H01L 2224/29305; H01L 2224/29309; H01L 2224/29311; H01L 2224/83191; H01L 2224/83201; H01L 2224/83855

(57) ABSTRACT

A thermal interface material (TIM), an integrated circuit assembly, and a method for thermally connecting layers are provided. The TIM comprises a polymer component and liquid metal droplets dispersed throughout the polymer component. The polymer component comprises a first polymer and at least one of a second polymer, a third polymer, and a fourth polymer. The first polymer comprises a vinyl terminated polydimethylsiloxane having a molecular weight (MW)<30,000 g/mol. The second polymer comprises a vinyl terminated polydimethylsiloxane having a MW<30,000 g/mol. The third polymer comprises an alkyl terminated poly dimethylsiloxane having a MW≥30,000 g/mol. The fourth polymer comprises polybutadiene. The TIM has a strain limit of at least 100% and the TIM has a lap shear strength of at least 1 MPa.

### FIELD

The present disclosure relates to a thermal interface material, an integrated circuit assembly, and a method for thermally connecting layers.

### BACKGROUND

A thermal interface material (TIM) can be used to thermally connect two or more layers together. For example, TIMs are often used in CPU packages to thermally connect the CPU die to the integrated heat spreader (IHS) of the CPU package. There are various types of TIMs that may be used. However, current TIMs present challenges.

### SUMMARY

In one general aspect, the present invention is directed to an integrated circuit assembly comprising an integrated circuit die, an upper layer, and a thermal interface material disposed in contact with the integrated circuit die and the upper layer. Wherein the thermal interface material is between the integrated circuit die and the upper layer. The thermal interface material comprises 8% to 70% by volume of a polymer component based on a total volume of the thermal interface material and at least 30% by volume of liquid metal droplets based on total volume of the thermal interface material. The liquid metal droplets are dispersed throughout the polymer component. The polymer component comprises 5% to 99% by weight of a first polymer comprising a vinyl terminated polydimethylsiloxane based on the total weight of the polymer component and at least one of 5% to 95% by weight of a second polymer, 1% to 25% by weight of a third polymer, and 5% to 20% of a fourth polymer, all based on the total weight of the polymer component. The second polymer comprises a vinyl terminated polydimethylsiloxane and the third polymer comprises an alkyl terminated polydimethylsiloxane. The first polymer has a molecular weight of less than 30,000 g/mol, the second polymer has a molecular weight of at least 30,000 g/mol, and the third polymer has a molecular weight of at least 30,000 g/mol. The fourth polymer comprises polybutadiene. Wherein the thermal interface material, when cured, has a strain limit of at least 100% and wherein the thermal interface material has a lap shear strength of at least 1 MPa.

In another general aspect, the present invention is directed to a method comprising applying a thermal interface material on an integrated circuit die, such that the thermal interface material is between the integrated circuit die and an upper layer of a circuit assembly. The thermal interface material comprises 8% to 70% by volume of a polymer component based on a total volume of the thermal interface material and at least 30% by volume of liquid metal droplets based on total volume of the thermal interface material. The liquid metal droplets are dispersed throughout the polymer component. The polymer component comprises 5% to 99% by weight of a first polymer comprising a vinyl terminated polydimethylsiloxane based on the total weight of the polymer component and at least one of 5% to 95% by weight of a second polymer, 1% to 25% by weight of a third polymer, and 5% to 20% by weight of a fourth polymer based on the total weight of the polymer component. The second polymer comprises a vinyl terminated polydimethylsiloxane and the third polymer comprises an alkyl terminated polydimethylsiloxane. The first polymer has a molecular weight of less than 30,000 g/mol, the second polymer has a molecular weight of at least 30,000 g/mol, and the third polymer has a molecular weight of at least 30,000 g/mol. The fourth polymer comprises polybutadiene. Wherein the thermal interface material, when cured, has a strain limit of at least 100%. Compressing the integrated circuit assembly thereby deforming the liquid metal droplets, wherein an average particle size of the liquid metal droplets in the thermal interface material prior to applying is greater than a bondline distance formed between the die and the upper layer in a cured assembly formed therefrom. The method comprises curing the thermal interface material thereby forming the cured assembly. Wherein the thermal interface material has a lap shear strength of at least 1 MPa.

The present invention can provide a low contact resistance and strong adhesion at the material interfaces, a low thermal resistance through the material, and a desirable stretchability. The low contact resistance can be enabled by the application of the polymer in an uncured state so that the polymer and liquid metal droplets can conform to the surface of the layer to achieve a desired contact resistance. The low thermal resistance through the material can be enabled by liquid metal droplets, including the size and/or shape of the liquid metal droplets. The strong adhesion and stretchability can be enabled by the composition of the polymer component. Additionally, the methods described herein may not need as high a pressure to install as compared to methods due to application of the polymer in the uncured state. Further, curing the polymer can inhibit pump out of the liquid metal droplets. These and other benefits realizable from various embodiments of the present invention will be apparent from the description that follows.

### BRIEF DESCRIPTION OF THE DRAWINGS

The features and advantages of various examples of the present invention, and the manner of attaining them, will become more apparent, and the examples will be better understood by reference to the following description of examples taken in conjunction with the accompanying drawing, wherein:

FIG. 1 is a schematic diagram of a container comprising a TIM emulsion according to the present disclosure;

FIG. 2A is a side cross-section view of an integrated circuit assembly comprising a TIM according to the present disclosure;

FIG. 2B is a side cross-section view of an integrated circuit assembly comprising a TIM according to the present disclosure;

FIG. 3A is a detail view of area 3A of the integrated circuit assembly in FIG. 2A prior to compressing the integrated circuit assembly; and

FIG. 3B is the integrated circuit assembly of FIG. 3A after compressing the integrated circuit assembly.

Corresponding reference characters indicate corresponding parts throughout the several views. The exemplifications set out herein illustrate certain examples, in one form, and such exemplifications are not to be construed as limiting the scope of the examples in any manner.

### DETAILED DESCRIPTION

Certain exemplary aspects of the present invention will now be described to provide an overall understanding of the principles of the composition, function, manufacture, and use of the compositions and methods disclosed herein. An example or examples of these aspects are illustrated in the accompanying drawing. Those of ordinary skill in the art will understand that the compositions, articles, and methods specifically described herein and illustrated in the accompanying drawing are non-limiting exemplary aspects and that the scope of the various examples of the present invention is defined solely by the claims. The features illustrated or described in connection with one exemplary aspect may be combined with the features of other aspects. Such modifications and variations are intended to be included within the scope of the present invention.

Applying a material to an integrated circuit die of an integrated circuit assembly such that the material is between the integrated circuit die and an integrated heat spreader (IHS) can require balancing the thermal resistance through the material, the contact resistance at the material interfaces, the adhesion of the material, and the stretchability of the material. For example, a polymeric material may have a low contact resistance at the material interfaces but a high thermal resistance through the material. A solid metal may have a low thermal resistance through the material but a high contact resistance at the material interfaces. Additionally, some solid materials (polymeric or metal) may require a large pressure during installation to achieve a desired contact resistance. Further, some materials may not achieve a desired adhesion thereby leading to failure of the formed assembly and/or some materials may not desirably stretch and therefore detach from a substrate that may warp during operation of an integrated circuit. Thus, the present invention provides, in various embodiments, an integrated circuit assembly and a method for thermally connecting two layers that can provide a low contact resistance and strong adhesion at the material interfaces, a low thermal resistance through the material, and a desirable stretchability. The integrated circuit assembly according to the present disclosure can comprise a thermal interface material (TIM) comprising a polymer component with liquid metal droplets dispersed through the polymer.

As used in this specification, the terms “polymer” and “polymeric” means prepolymers, oligomers, and both homopolymers and copolymers. As used in this specification, “prepolymer” means a polymer precursor capable of further reactions or polymerization by a reactive group or reactive groups to form a higher molecular mass or cross-linked state.

The TIM can comprise at least 8% of the polymer component by volume based on the total volume of the TIM, such as, for example, at least 10% of the polymer, at least 15% of the polymer, at least 20% of the polymer, at least 25% of the polymer component, at least 30% of the polymer component, at least 35% of the polymer component, at least 40% of the polymer component, at least 45% of the polymer component, or at least 50% of the polymer component, all by volume based on the total volume of the TIM. The TIM can comprise no greater than 70% of the polymer component by volume based on the by total volume of the TIM, such as, for example, no greater than 65% of the polymer component, no greater than 60% of the polymer component, no greater than 55% of the polymer component, no greater than 50% of the polymer component, no greater than 45% of the polymer component, or no greater than 40% of the polymer component, all by volume based on the total volume of the TIM. The TIM can comprise a range of 8% to 70% of the polymer component by volume based on the total volume of the TIM, such as, for example, 20% to 50% of the polymer component, 30% to 50% of the polymer component, 30% to 60% of the polymer component, 40% to 60% of the polymer component, or 40% to 70% of the polymer component, all by volume based on the total volume of the TIM.

The polymer component can be a thermosetting polymer. As used herein, the term “thermosetting” refers to polymers that “set” irreversibly upon curing or cross-linking, where the polymer chains of the polymeric components are joined together by covalent bonds, which is often induced, for example, by heat or radiation. In various examples, curing or a cross-linking reaction can be carried out under ambient conditions. Once cured or cross-linked, a thermosetting polymer may not melt upon the application of heat and can be insoluble in conventional solvents. In certain embodiments, the polymer can be elastomeric (e.g., rubbery, soft, stretchy).

The polymer component can comprise a first polymer and at least one of a second polymer, a third polymer, and a fourth polymer. In various examples, the polymer component comprises the first polymer, the second polymer, the third polymer, and the fourth polymer. The first polymer comprises a vinyl terminated polydimethylsiloxane, such as, for example, a divinyl terminated polydimethylsiloxane (e.g., CAS No. 68083-19-2). The first polymer can comprise a molecular weight of less than 30,000 g/mol, such as, for example, no greater than 26,000 g/mol, or no greater than 20,000 g/mol. The first polymer can comprise a functionality of at least 3. The polymer component can comprise at least 5% by weight of the first polymer based on the total weight of the polymer component, such as, for example, at least 10%, at least 20%, at least 30%, at least 40%, or at least 50%, all by weight of the first polymer based on the total weight of the polymer component. The polymer component can comprise no greater than 99% by weight of the first polymer based on the total weight of the polymer component, such as, for example, no greater than 95%, no greater than 90%, no greater than 80%, no greater than 75%, or no greater than 70%, all by weight of the first polymer based on the total weight of the polymer component. For example, the polymer component can comprise a range of 5% to 99% by weight of the first polymer component based on the total weight of the polymer component, such as, for example, 5% to 90%, 20% to 80%, or 40% to 75%, all by weight of the first polymer component based on the total weight of the polymer component.

Molecular weight of a polymer can be determined according to ASTM D4001-20.

The second polymer comprises a vinyl terminated polydimethysiloxane, such as, for example, a divinyl terminated polydimethylsiloxane (e.g., CAS No. 68083-19-2). The second polymer can comprise a molecular weight of at least 30,000 g/mol, such as, for example, at least 40,000 g/mol, at least 50,000 g/mol, at least 60,000 g/mol, at least 70,000 g/mol, at least 80,000 g/mol, or at least 90,000 g/mol. The second polymer can comprise a molecular weight in a range of 30,000 g/mol to 500,000 g/mol, such as, for example, in a range of 40,000 g/mol to 400,000 g/mol, in a range of 50,000 g/mol to 200,000 g/mol, or in a range of 80,000 g/mol to 150,000 g/mol. The second polymer can be difunctional. The polymer component can comprise at least 5% by weight of the second polymer based on the total weight of the polymer component, such as, for example, at least 10%, at least 20%, at least 30%, at least 40%, or at least 50%, all by weight of the second polymer based on the total weight of the polymer component. The polymer component can comprise no greater than 95% by weight of the second polymer based on the total weight of the polymer component, such as, for example, no greater than 95%, no greater than 90%, no greater than 75%, no greater than 50%, no greater than 40%, no greater than 30%, or no greater than 25%, all by weight of the second polymer based on the total weight of the polymer component. For example, the polymer component can comprise a range of 5% to 95% by weight of the second polymer based on the total weight of the polymer component, such as, for example, a range of 5% to 90%, a range of 5% to 50%, a range of 5% to 25%, or a range of 10% to 25%, all by weight of the second polymer based on the total weight of the polymer component.

The third polymer can comprise an alkyl terminated polydimethylsiloxane, such as, for example, a dialkyl terminated polydimethylsiloxane (e.g., CAS No. 63148-62-9). The molecular weight of the third polymer can be at least 30,000 g/mol, such as, for example, at least 40,000 g/mol, at least 50,000 g/mol, at least 60,000 g/mol, at least 70,000 g/mol, at least 80,000 g/mol, or at least 90,000 g/mol. The molecular weight of the third polymer can be in a range of 30,000 g/mol to 500,000 g/mol, such as, for example, in a range of 40,000 g/mol to 400,000 g/mol, in a range of 50,000 g/mol to 200,000 g/mol, or in a range of 80,000 g/mol to 150,000 g/mol. The polymer component can comprise at least 1% by weight of the third polymer based on the total weight of the polymer component, such as, for example, at least 2.5%, at least 5%, or at least 10%, all by weight of the third polymer based on the total weight of the polymer component. The polymer component can comprise no greater than 25% by weight of the third polymer based on the total weight of the polymer component, such as, for example, no greater than 20%, no greater than 15%, no greater than 10%, or no greater than 5%, all by weight of the third polymer based on the total weight of the polymer component. For example, the polymer component can comprise a range of 1% to 25% by weight of the third polymer based on the total weight of the polymer component, such as, for example, a range of 1% to 20%, a range of 5% to 20%, a range of 5% to 10%, or a range of 1% to 10%, all by weight of the third polymer based on the total weight of the polymer component.

The fourth polymer can comprise polybutadiene. The polymer component can comprise at least 5% of the fourth polymer based on the total weight of the polymer component, such as, for example, at least 8% of the fourth polymer, or at least 10% of the fourth polymer all based on the total weight of the polymer component. The polymer component can comprise no greater than 20% of the fourth polymer based on the total weight of the polymer component, such as, for example, no greater than 15% of the fourth polymer, or no greater than 12% of the fourth polymer all based on the total weight of the polymer component. The polymer component can comprise a range of 5% to 20% by weight of the fourth polymer based on the total weight of the polymer component, such as, for example, a range of 8% to 20%, or a range of 8% to 15%, all based on the total weight of the polymer component. The fourth polymer may react with the first polymer and/or form an emulsion with the first polymer. The fourth polymer can be added to the polymer component to maintain a desirable viscosity of the polymer component.

The polymer component can comprise a range of 5% to 99% by weight of the first polymer, a range of 5% to 95% by weight of the second polymer, a range of 1% to 25% by weight of the third polymer, and a range of 5% to 20% of the fourth polymer, all based on the total weight of the polymer component. In various embodiments, the polymer component can comprise a range of 5% to 90% by weight of the first polymer, a range of 5% to 25% by weight of the second polymer, a range of 5% to 10% by weight of the third polymer, and a range of 5% to 20% of the fourth polymer all based on the total weight of the polymer component. In certain embodiments, the polymer component can comprise a range of 40% to 75% by weight of the first polymer, a range of 10% to 25% by weight of the second polymer, and a range of 1% to 10% by weight of the third polymer, all based on the total weight of the polymer component.

The first polymer can be balanced with the second polymer and/or the third polymer within the polymer component to achieve a desired crosslink density of the cured polymer component. For example, increasing the amounts of the second polymer and/or the third polymer relative to the first polymer, can decrease the cross link density of the cure polymer component. Therefore, balancing the first polymer, the second polymer, and/or the third polymer can achieve a desirable cross link density while achieving a desirable adhesion and stretchability of the resulting polymer component.

In certain embodiments, the polymer component further comprises a silane coupling agent based on the total weight of the polymer component, such as, for example, vinylisopropyl triethoxy silane. The polymer component can comprise a range of 0.1% to 0.5% by weight of the silane coupling agent based on the total weight of the polymer component. In various embodiments, the polymer component further comprises a catalyst.

The polymer component can comprise other additives as desired. For example, the polymer component may also include a cross-linking agent that may comprise, for example, aminoplasts, polyisocyanates (including blocked isocyanates), polyepoxides, beta-hydroxyalkylamides, polyacids, anhydrides, organometallic acid-functional materials, polyamines, polyamides, or a combination thereof. The first, second, third, and/or fourth polymer may have functional groups that are reactive with the cross-linking agent.

The liquid metal for the TIM can comprise gallium, a gallium alloy, indium, an indium alloy, tin, a tin alloy, mercury, a mercury alloy, or a combination thereof. The liquid metal can be in the liquid phase at least at a temperature of at least −20 degrees Celsius (e.g., in its bulk form, can comprise a melting point of less than −20 degrees Celsius), such as, for example, at least −19 degrees Celsius, at least −10 degrees Celsius, at least 0 degrees Celsius, at least 5 degrees Celsius, at least 10 degrees Celsius, at least 15 degrees Celsius, at least 20 degrees Celsius, or at least 25 degrees Celsius. The liquid metal can be in the liquid phase at least at a temperature of no greater than 30 degrees Celsius (e.g., in its bulk form, can comprise a melting point of less than 30 degrees Celsius), such as, for example, no greater than 25 degrees Celsius, no greater than 20 degrees Celsius, no greater than 15 degrees Celsius, no greater than 10 degrees Celsius, no greater than 5 degrees Celsius, no greater than 0 degrees Celsius, or no greater than −10 degrees Celsius. The liquid metal can be in the liquid phase at least at a temperature in a range of −20 degrees Celsius to 30 degrees Celsius (e.g., in its bulk form, can comprise a melting point of less than a temperature in a range of −20 degrees Celsius to 30 degrees Celsius), such as, for example, −19 degrees Celsius to 30 degrees Celsius, −19 degrees Celsius to 25 degrees Celsius, or −19 degrees Celsius to 20 degrees Celsius. The determination of whether the liquid phase is achieved at the respective temperature can be made at a pressure of 1 atmosphere absolute. In certain embodiments, the TIM can comprise Gallium Indium Tin alloy (e.g., GALINSTAN™, METSPEC 51™) and a melting point of −19 degrees Celsius.

The TIM can comprise at least 30% liquid metal droplets by volume based on the total volume of the TIM, such as, for example, at least 35% liquid metal droplets, at least 40% liquid metal droplets, at least 45% liquid metal droplets, at least 50% liquid metal droplets, at least 55% liquid metal droplets, or at least 60% liquid metal droplets, all by volume based on the total volume of the liquid metal droplets. The TIM can comprise no greater than 92% liquid metal droplets by volume based on the total volume of the TIM, such as, for example, no greater than 90% liquid metal droplets, no greater than 80% liquid metal droplets, no greater than 75% liquid metal droplets, no greater than 70% liquid metal droplets, no greater than 65% liquid metal droplets, or no greater than 60% liquid metal droplets, all by volume based on the total volume of the TIM. The TIM can comprise a range of 30% to 80% liquid metal droplets by total volume of the TIM, such as, for example, 40% to 75% liquid metal droplets, 45% to 75% liquid metal droplets, 45% to 70% liquid metal droplets, or 50% to 70% liquid metal droplets, all based on the total volume of the TIM.

In various embodiments, the TIM further comprises 0.1-0.5% by weigh of a fumed silica based on the total weight of the TIM. The fumed silica can enhance the stability of the uncured TIM during storage such that the components within the uncured TIM do not phase separate or settle.

The TIM, when cured, can comprise a strain limit of at least 100%, such as, for example, at least 200%, or at least 300%. The TIM, when cured, can comprise a strain limit of no greater than 600%, such as, for example, no greater than 500%, or no greater than 400%. For example, the TIM, when cured, can comprise a strain limit in a range of 100% to 600%, such as, for example, 100% to 500%.

The TIM, when cured, can comprise a 10% Young's modulus of no greater than 3000 kPa, such as, for example, no greater than 2000 kPa, no greater than 1500 kPa, or no greater than 800 kPa. For example, the TIM, when cured, can comprise a Young's modulus in a range of 100 kPa to 3000 kPa, such as, for example, in a range of 500 kPa to 1500 kPa or in a range of 600 kPa to 800 kPa. In various embodiments, the adhesion strength of the TIM can be greater than the cohesive strength of the TIM. The 10% Young modulus can be used to estimate the softness of materials because many polymers do not have a linear stress strain behavoir. Softer materials can introduce less forces during the warpage of an assembly, and therefore less chance of delamination or breaking of the TIM.

To measure the strain limit and 10% Young's modulus, a dog-bone shape sample with length of 50 mm, width of 10 mm, and thickness of between 0.3 to 0.6 mm of the TIM is prepared. Then the sample is clamped at top and bottom using a Mark-10 mechanical tester. The actual free length of the sample is then measured using a caliper. The sample is stretched at a displacement rate of 10-50 mm/min until failure. During the stretching, the strain at break is measured to determine the Young's modulus and the length of the sample at break is measured to determine the strain limit.

The TIM can be created by forming an emulsion of the polymer component and the liquid metal such that liquid metal droplets are substantially dispersed throughout the polymer. For example, the polymer component and liquid metal droplets can be mixed together with a high shear mixer, a centrifugal mixer, by shaking in a container, a mortar and pestle, sonication, or a combination thereof. More details about exemplary ways to form the emulsion are described in (1) published PCT WO/2019/136252, entitled “Method of Synthesizing a Thermally Conductive and Stretchable Polymer Composite” and (2) published U.S. application US 2017/0218167, entitled “Polymer Composite with Liquid Phase Metal Inclusions,” both of which are incorporated herein by reference in their entirety. The composition and/or mixing techniques can be chosen such that the viscosity of the TIM emulsion in an uncured state is no greater than 500,000 cP (centipoise), such as, for example, no greater than 200,000 cP, no greater than 200,000 cP, no greater than 150,000 cP, no greater than 100,000 cP, no greater than 50,000 cP, no greater than 15,000 cP, no greater than 14,000 cP, no greater than 13,000 cP, no greater than 12,000 cP, no greater than 11,000 cP, or no greater than 10,000 cP. The viscosity of the TIM emulsion can be measured by a rotary viscometer or a cone and plate viscometer at room temperature. The viscosity measurement can be performed using a parallel plate Rheometer (TA Instrument) at a select frequency suitable to produce a static viscosity (e.g., since the material is a non-newtonian fluid).

The composition and/or mixing techniques can be selected to achieve a desired average particle size of the liquid metal droplets in the TIM. The average particle size of the liquid metal droplets can be at least 1 micron, such as, for example, at least 5 microns, at least 10 microns, at least 20 microns, at least 30 microns, at least 35 microns, at least 40 microns, at least 50 microns, at least 60 microns, at least 70 microns, at least 80 microns, at least 90 microns, at least 100 microns, at least 120 microns, or at least 150 microns. The average particle size of the liquid metal droplets can be no greater than 200 micron, such as, for example, no greater than 150 microns, no greater than 120 microns, no greater than 100 microns, no greater than 90 microns, no greater than 80 microns, no greater than 70 microns, no greater than 60 microns, no greater than 50 microns, no greater than 40 microns, no greater than 35 microns, no greater than 30 microns, no greater than 20 microns, no greater than 10 microns, or no greater than 5 microns. For example, the average particle size of the liquid metal droplets can be in a range of 1 microns to 200 microns, such as, for example, 5 microns to 150 microns, 35 microns to 150 microns, 35 microns to 70 microns, or 5 microns to 100 microns.

As used herein, “average particle size” refers to the mean average size measured using microscopy (e.g., optical microscopy or electron microscopy). The size can be the diameter of spherical particles or the length along the largest dimension if ellipsoidal or otherwise irregularly shaped particle.

The polydispersity of the liquid metal droplets can be unimodal or multimodal (e.g., bimodal, trimodal). Utilizing a multimodal polydispersity can increase the packing density of the liquid metal droplets in the TIM. In certain embodiments where the polydispersity is unimodal, the polydispersity of the liquid metal droplets in the polymer can be in a range of 0.3 to 0.4.

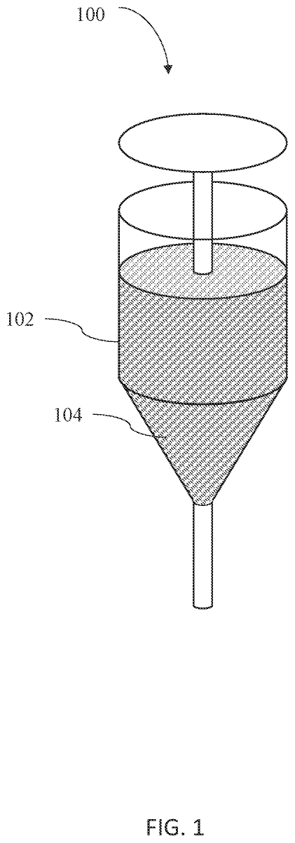

The TIM can be stored in a container 100 as illustrated in FIG. 1 prior to use. For example, the container can comprise walls 102 defining a cavity and the TIM emulsion 104 can be stored in the cavity. The TIM 104 can be in an uncured state in the container 100. Storage of the TIM 104 in the container 100 can inhibit curing of the TIM 104. The container 100 can be a pillow pack, a syringe, a beaker, a jar, a bottle, a drum, or a combination thereof. In various examples, the container 100 can be a ready to use dispensing device, such as, for example, a pillow pack or a syringe. In other examples, the TIM 104 may not be stored and can be used after creation of the emulsion without storage.

As used in this specification, the terms “cure” and “curing” refer to the chemical cross-linking of components in an emulsion or material applied over a substrate or the increase of viscosity of the components in the emulsion or material applied over the substrate. Accordingly, the terms “cure” and “curing” do not encompass solely physical drying of an emulsion or material through solvent or carrier evaporation. In this regard, the term “cured” refers to the condition of an emulsion or material in which a component of the emulsion or material has chemically reacted to form new covalent bonds in the emulsion or material (e.g., new covalent bonds formed between a binder resin and a curing agent).

Curing of a thermosetting polymer can be achieved by applying a temperature of at least −20 degrees Celsius to the TIM 104, such as, for example, at least 10 degrees Celsius, at least 50 degrees Celsius, at least 100 degrees Celsius, or at least 150 degrees Celsius. Curing can be achieved by applying a temperature of no greater than 300 degrees Celsius to the TIM 104, such as, for example, no greater than 250 degrees Celsius, no greater than 200 degrees Celsius, no greater than 150 degrees Celsius, no greater than 100 degrees Celsius, or no greater than 50 degrees Celsius. Curing can be achieved by applying a temperature in a range of −10 degrees Celsius to 300 degrees Celsius to the TIM 104, such as, for example, 10 degrees Celsius to 200 degrees Celsius or 50 degrees Celsius to 150 degrees Celsius. For example, curing can comprise thermally baking the TIM. The temperature can be applied for a time period of greater than 1 minute, such as, for example, greater than 5 minutes, greater than 30 minutes, greater than 1 hour, or greater than 2 hours.

The TIM 104 can be dispensed from the container 100 and applied to a layer in an uncured state. Thereafter, the TIM 104 can be cured to form a cured TIM 104. Curing the TIM 104 can comprise heating the TIM 104, adding a catalyst to the TIM 104, exposing the TIM 104 to air, applying pressure to the TIM 104, or a combination thereof. Curing the TIM 104 can increase the viscosity of the TIM emulsion to greater than 15,000 cP, such as, for example, greater than 20,000 cP, greater than 30,000 cP, greater than 50,000 cP, greater than 100,000 cP, greater than 150,000 cP, greater than 200,000 cP, or greater than 250,000 cP. For example, the polymer in the TIM 104 can be cured. In various examples, the TIM 104 can be an adhesive. The polymer in the TIM 104 can be selected to reduce off-gasing of the TIM 104 during curing.

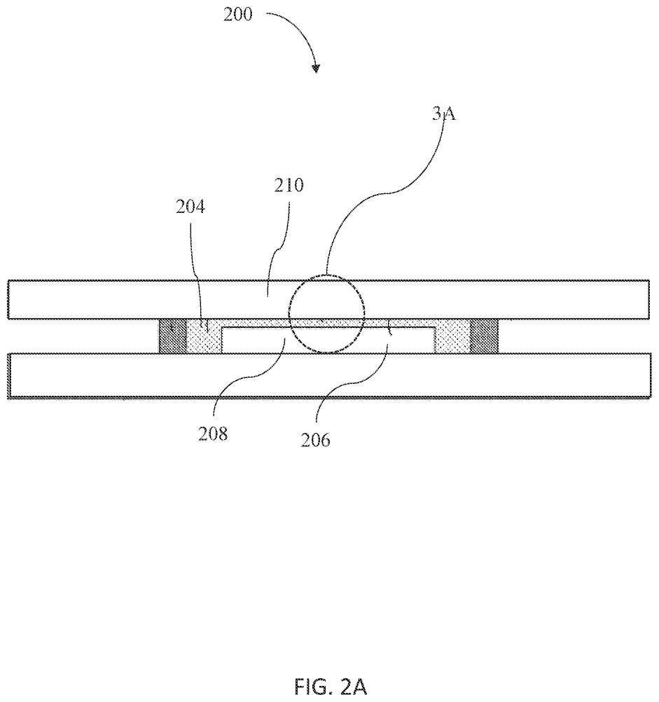

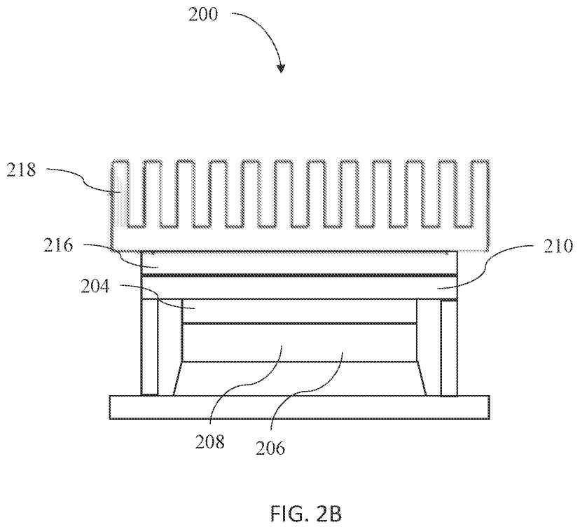

The TIM according to the present disclosure can be applied to a first layer such that the TIM is between two layers of an assembly including the first layer and a second layer. The first layer can be a heat-generating electronic component (e.g., integrated circuit) and the second layer can be an upper layer that can be thermally conductive. For example, the upper layer can be a heat spreader, a heat sink, or packaging. Thereafter, the assembly can be compressed thereby deforming the liquid metal droplets in the TIM and the TIM can be cured to form the assembly. Applying the TIM 104 in an uncured state can achieve a desired contact resistance and enable lower pressures to be used when compressing an assembly. The TIM can be applied to various layers and devices and it is described below with reference to FIGS. 2A-B with reference to an integrated circuit assembly but is not limited to only an integrated circuit assembly.

Referring to FIG. 2A, a TIM 204 can be applied to an integrated circuit die 206 of an integrated circuit 208 of an integrated circuit assembly 200 such that the TIM 204 can be between and in contact with the integrated circuit die 206 and an upper layer 210 of the integrated circuit assembly 200. Applying the TIM 204 to the integrated circuit die 206 can comprise spray coating, spin coating, dip coating, roll coating, flow coating, film coating, brush coating, extrusion, dispensing, or a combination thereof. The TIM 204 can be applied in an uncured state such that the TIM is conformable to the surfaces of the integrated circuit die 206 and the upper layer 210 such that a desired level of surface contact therebetween can be achieved. In various examples, the TIM 204 can be applied directly to the integrated circuit die 206 and, thereafter, the upper layer 210 can be applied directly to the TIM 204. In various other examples, the TIM 204 can be applied directly to the upper layer 210 and, thereafter, the integrated circuit die 206 can be applied directly to the TIM 204. In various examples, after application of the TIM 204, the TIM 204 can be in direct contact with the integrated circuit die 206 and the upper layer 210. In certain examples, the application of the TIM 204 may be limited to the surfaces of the integrated circuit die 206 such that the TIM 204 can be efficiently used.

As used in this specification, particularly in connection with layers, films, or materials, the terms “on,” “onto,” “over,” and variants thereof (e.g., “applied on,” “formed on,” “deposited on,” “provided on,” “located on,” and the like) mean applied, formed, deposited, provided, or otherwise located over a surface of a substrate but not necessarily in contact with the surface of the substrate. For example, a TIM “applied on” a substrate does not preclude the presence of another layer or other layers of the same or different composition located between the applied TIM and the substrate. Likewise, a second layer “applied on” a first layer does not preclude the presence of another layer or other layers of the same or different composition located between the applied second layer and the applied TIM.

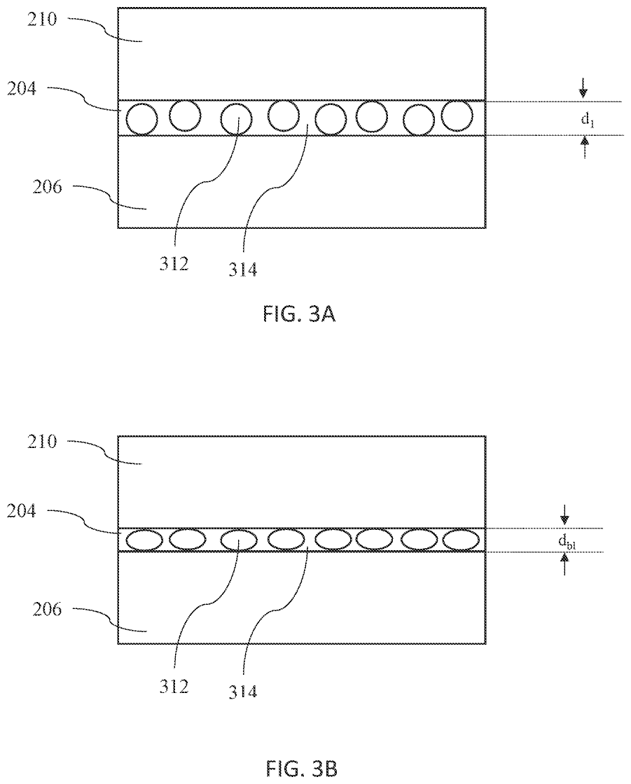

The integrated circuit assembly 200 can be compressed. For example, referring to the detailed views in FIGS. 3A-3B, the integrated circuit die 206 and the upper layer 210 can be urged together such that a first distance, d₁, can decrease to a second, bondline distance, d_{bl}. The average particle size of the liquid metal droplets 312 in the TIM 204 prior to applying and/or a compressing process can be selected to be greater than a desired bondline distance, d_{bl}, formed between the integrated circuit die 206 and the upper layer 210. For example, the average particle size of the liquid metal droplets 312 prior to applying and/or a compressing process can be greater than the bondline distance, d_{bl}, such as, for example, 1% greater than the bondline distance, d_{bl}, 2% greater than the bondline distance, d_{bl}, 5% greater than the bondline distance, d_{bl}, 10% greater than the bondline distance, d_{bl}, 15% greater than the bondline distance, d_{bl}, 20% greater than the bondline distance, d_{bl}, 30% greater than the bondline distance, d_{bl}, 40% greater than the bondline distance, d_{bl}, 50% greater than the bondline distance, d_{bl}, or 75% greater than the bondline distance, d_{bl}. The average particle size of the liquid metal droplets 312 prior to applying and/or a compressing process can be no more than 100% greater than the bondline distance, d_{bl}, such as, for example, no more than 75% greater than the bondline distance, d_{bl}, no more than 50% greater than the bondline distance, d_{bl}, no more than 40% greater than the bondline distance, d_{bl}, no more than 30% greater than the bondline distance, d_{bl}, no more than 20% greater than the bondline distance, d_{bl}, no more than 15% greater than the bondline distance, d_{bl}, no more than 10% greater than the bondline distance, d_{bl}, no more than 5% greater than the bondline distance, d_{bl}, or no more than 2% greater than the bondline distance, d_{bl}. The average particle size of the liquid metal droplets 312 prior to applying and/or a compressing process can be in a range of 1% to 100% greater than the bondline distance, d_{bl}, such as, for example, 1% to 50% greater than the bondline distance, d_{bl}, 1% to 30% greater than the bondline distance, d_{bl}, 2% to 30% greater than the bondline distance, d_{bl}, or 5% to 20% greater than the bondline distance, d_{bl}.

Compressing the integrated circuit assembly 200 can apply a force to the TIM 204 and can deform the liquid metal droplets 312 dispersed within the polymer component 314 of the TIM 204. Since the TIM 204 is in the uncured state, the polymer is still conformable and moveable such that the compressing force can deform the liquid metal droplets 312. The liquid metal droplets 312 can be in the liquid phase during deformation such that a lower pressure is required for the compression and a desired deformation is achieved.

The liquid metal droplets 312 can be generally spherical as shown in FIG. 3A and thereafter can be generally ellipsoidal as shown in FIG. 3B. In various examples, the liquid metal droplets 312 prior to compressing can have a first average aspect ratio and after compressing the liquid metal droplets 312 can have a second average aspect ratio. The second average aspect ratio can be different that the first average aspect ratio. For example, the second average aspect ratio can be greater than the first average aspect ratio. The average aspect ratio can be a mean ratio of the width of the liquid metal droplets 312 to the height of the liquid metal droplets 312. In various examples, the first aspect ratio can be 1 and the second aspect ratio can be greater than 1. In certain embodiments, the first aspect ratio can be in a range of 1 to 1.5. In certain embodiments, the second aspect ratio can be at least 0.5 greater than the first aspect ratio, such as, for example, at least 1 greater than the first aspect ratio, at least 2 greater than the first aspect ratio, or at least 5 greater than the first aspect ratio. The width of the liquid metal droplets 312 can be substantially aligned with the longitudinal plane of the TIM 204 in the circuit assembly 200 and the height of the liquid metal droplets 312 can be substantially aligned with the thickness of the TIM 204 (e.g., the distance, d₁). The width of the liquid metal droplets 312 can increase upon compression of the circuit assembly 200. For example, in certain embodiments, the radius of a spherical liquid metal droplets prior to compressing can be 100 μm (e.g., first aspect ratio of 1) and after compression to a bondline thickness of 20 μm, the liquid metal drop can be deformed to an ellipsoidal shape with a 316 um width (e.g., second aspect ratio of 15.6).

In certain examples, the liquid metal droplets 312 can be aligned in a substantially monolayer as shown in FIG. 3B after compressing. The monolayer can be achieved by selecting the average particle size of the liquid metal droplets 312 and the bondline distance, d_{bl}. Configuring the liquid metal droplets 312 in a monolayer can reduce the thermal resistance of the TIM 204.

The TIM 204 can be cured thereby forming the integrated circuit assembly 200. Curing the TIM 204 can increase the viscosity of the polymer component 314 and can harden the polymer component 314. For example, the polymer component 314 can become a solid. In various examples, the polymer component 314 after curing is elastomeric. Curing the polymer component 314 can inhibit pump out of the liquid metal droplets 312 during thermal cycling of the integrated circuit assembly 200 and can provide a mechanical bond (e.g., adhesive bond) between the die 206 and the upper layer 210.

The cured TIM 204 can provide a desirable adhesion between the integrated circuit die 206 and an upper layer 210. For example, the TIM 204 can comprise a lap shear strength of at least 1 MPa, such as, for example, at least 2 MPa, at least 3 MPa, at least 4 MPa, at least 5 MPa, or at least 6 MPa. In various examples, the TIM 204 can comprise a lap shear strength in a range of 1 MPa to 6 MPa. The Lap Shear can be measured according to ASTM D1002.

The integrated circuit assembly 200 can comprise a bondline distance, d_{bl}, formed between the die 206 and the upper layer 210 in the cured assembly that is no greater than 150 microns, such as, for example, no greater than 145 microns, no greater than 140 microns, no greater than 120 microns, no greater than 100 microns, no greater than 80 microns, no greater than 70 microns, no greater than 50 microns, no greater than 40 microns, no greater than 35 microns, or no greater than 30 microns. The assembly 200 can comprise a bondline distance, d_{bl}, formed between the die 206 and the upper layer 210 in the cured assembly that is at least 15 microns, such as, for example, at least 30 microns, at least 35 microns, at least 40 microns, at least 50 microns, at least 70 microns, at least 80 microns, at least 100 microns, at least 120 microns, at least 140 microns, or at least 145 microns. The assembly 200 can comprise a bondline distance, d_{bl}, formed between the die 206 and the upper layer 210 in the cured assembly that is in a range of 15 microns to 150 microns, such as, for example, in a range of 15 microns to 90 microns, in a range of 15 microns to 70 microns, in a range of 30 microns to 70 microns, in a range of 35 microns to 70 microns, or in a range of 15 microns to 100 microns.

The curing can occur for a first time period and the compressing can occur for a second time period. The first time period can be after or at least partially overlap with the second time period. For example, the liquid metal droplets 312 may be deformed prior to substantial curing of the polymer component 314 such that a lower compression pressure may be used to deform the liquid metal droplets 312.

The average particle size and deformation of the liquid droplets 312 can improve the thermal resistance value of the TIM 204. For example, the TIM 204 after curing can comprise a thermal resistance value of no greater than 30 (° K*mm²)/W, such as, for example, no greater than 20 (° K*mm²)/W, no greater than 15 (° K*mm²)/W, no greater than 10 (° K*mm²)/W, no greater than 9 (° K*mm²)/W, no greater than 8 (° K*mm²)/W, no greater than 7 (° K*mm²)/W, or no greater than 5 (° K*mm²)/W. The TIM 204 after curing can comprise a thermal resistance value of at least 0.5 (° K*mm²)/W, such as, for example, at least 1 (° K*mm²)/W, at least 2 (° K*mm²)/W, at least 3 (° K*mm²)/W, at least 5 (° K*mm²)/W, or at least 10 (° K*mm²)/W. The TIM 204 after curing can comprise a thermal resistance value in a range of 0.5 (° K*mm²)/W to 30 (° K*mm²)/W, such as, for example, 0.5 (° K*mm²)/W to 20 (° K*mm²)/W, 0.5 (° K*mm²)/W to 15 (° K*mm²)/W, 1 (° K*mm²)/W to 10 (° K*mm²)/W, 2 (° K*mm²)/W to 10 (° K*mm²)/W, or 2 (° K*mm²)/W to 8 (° K*mm²)/W. The thermal resistance value can be measured using a DynTIM-S instrument available from Siemens (Munich, Germany), a TIMA instrument from NanoTest (Germany), and/or a LongWin LW 9389 (Taiwan).

The integrated circuit die 206 can comprise, for example, an integrated circuit, such as a processor or an ASIC, or a system-on-a-chip (SOC). The upper layer 210 can be an integrated heat spreader. The TIM 204 can be applied directly between the processor and the integrated heat spreader. For example, the TIM 204 can be a TIM1, a TIM 1.5, or a combination thereof. A TIM1 can be used to thermally connect an integrated circuit die and an integrated heat spreader in a lidded package. A TIM1.5 can be used to thermally connect an integrated circuit die to a heat sink in a bare die package.

In various other examples, referring to FIG. 2B, a TIM 216 can be applied between the upper layer 210 (e.g., integrated heat spreader) and a different upper layer 218. The upper layer 218 can comprise a heat sink. For example, the TIM 216 can be a TIM2.

In various other examples, the TIM according to the present disclosure can be used in a system on a package. For example, a single horizontal TIM layer can be in contact with multiple dies on one side (e.g., the integrated circuit can comprise multiple dies or multiple integrated circuits can be in contact with the same side of the TIM) and a upper layer or layers on a different side.

### EXAMPLES

The present disclosure will be more fully understood by reference to the following examples, which provide illustrative non-limiting aspects of the invention. It is understood that the invention described in this specification is not necessarily limited to the examples described in this section.

A comparative TIM, a first inventive TIM, a second inventive TIM, and a third inventive TIM were prepared with a polymer and liquid metal droplets. Each TIM had the volume % of liquid metal droplets. The liquid metal droplets comprised a Gallium Indium Tin alloy. The comparative TIM comprised a polymer component comprising 100% by weight of a vinyl terminated polydimethylsiloxane having a molecular weight of no greater than 30,000 g/mol and 10 parts per hundred (PHR) of the associated catalyst. The first inventive TIM comprised 60% by weight of a vinyl terminated polydimethylsiloxane having a molecular weight of no greater than 30,000 g/mol and 10 PHR of the associated catalyst, 20% by weight of a vinyl terminated polydimethylsiloxane polymer having a molecular weight of 92,000 g/mol, 10% by weight of an alkyl terminated polydimethylsiloxane having a molecular weight of 308,000 g/mol, 10% by weight of polybutadiene, and 0.5% by weight of a silane coupling agent, all based on the total weight of the polymer component. The second inventive TIM comprised 65% by weight of a vinyl terminated polydimethylsiloxane having a molecular weight of no greater than 30,000 g/mol and 10 PHR of the associated catalyst, 10% by weight of a vinyl terminated polydimethylsiloxane polymer having a molecular weight of 92,000 g/mol, 5% by weight of an alkyl terminated polydimethylsiloxane having a molecular weight of 308,000 g/mol, 20% by weight of polybutadiene and 0.5% by weight of a silane coupling agent, all based on the total weight of the polymer component. The third inventive TIM comprised 75% by weight of a vinyl terminated polydimethylsiloxane having a molecular weight of no greater than 30,000 g/mol and 10 PHR of the associated catalyst, 10% by weight of a vinyl terminated polydimethylsiloxane polymer having a molecular weight of 92,000 g/mol, 5% by weight of an alkyl terminated polydimethylsiloxane having a molecular weight having a molecular weight of 308,000 g/mol, 10% by weight of polybutadiene, and 0.5% by weight of a silane coupling agent, all based on the total weight of the polymer component.

Each TIM was cured and subject to a 180 degree peel test, which was a modified version of ASTM D1876-01. During the 180 degree peel test a strip of a sample with the width of 10 mm and thickness of 500 μm is adhered to a substrate by forming a film on the substrate and curing in an oven for the polymer to cure. The TIM is then peeled at an angle of 180° from the substrate. The comparative TIM was determined to have a near zero peel force and the entire TIM came off as a single piece. The first inventive TIM, the second inventive TIM, and the third inventive TIM exhibited peel strengths in a range of 20-50 N/m indicating a greater adhesion force was achieved. Additionally, in the first, second, and third inventive TIMs, high adhesion compared to the cohesion of the samples was observed, thereby resulting in the sample breaking at the connection to the substrate.

Additionally, the strain limit of each cured TIM was tested. The comparative TIM exhibited an average strain limit of 77%. The first inventive TIM exhibited an average strain limit of 155%, the second inventive TIM exhibited an average strain limit of 119%, and the third inventive TIM exhibited an average strain limit of 131.5%.

Those skilled in the art will recognize that the herein described compositions, articles, methods, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken as limiting.

With respect to the appended claims, those skilled in the art will appreciate that recited operations therein may generally be performed in any order. Also, although various operational flows are presented in a sequence(s), it should be understood that the various operations may be performed in other orders than those that are illustrated or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

Although various examples have been described herein, many modifications, variations, substitutions, changes, and equivalents to those examples may be implemented and will occur to those skilled in the art. Also, where materials are disclosed for certain components, other materials may be used. It is therefore to be understood that the foregoing description and the appended claims are intended to cover all such modifications and variations as falling within the scope of the disclosed examples. The following claims are intended to cover all such modification and variations.

Various features and characteristics are described in this specification to provide an understanding of the composition, structure, production, function, and/or operation of the invention, which includes the disclosed compositions, coatings, and methods. It is understood that the various features and characteristics of the invention described in this specification can be combined in any suitable manner, regardless of whether such features and characteristics are expressly described in combination in this specification. The Inventors and the Applicant expressly intend such combinations of features and characteristics to be included within the scope of the invention described in this specification. As such, the claims can be amended to recite, in any combination, any features and characteristics expressly or inherently described in, or otherwise expressly or inherently supported by, this specification. Furthermore, the Applicant reserves the right to amend the claims to affirmatively disclaim features and characteristics that may be present in the prior art, even if those features and characteristics are not expressly described in this specification. Therefore, any such amendments will not add new matter to the specification or claims and will comply with the written description, sufficiency of description, and added matter requirements.

Any numerical range recited in this specification describes all sub-ranges of the same numerical precision (i.e., having the same number of specified digits) subsumed within the recited range. For example, a recited range of “1.0 to 10.0” describes all sub-ranges between (and including) the recited minimum value of 1.0 and the recited maximum value of 10.0, such as, for example, “2.4 to 7.6,” even if the range of “2.4 to 7.6” is not expressly recited in the text of the specification. Accordingly, the Applicant reserves the right to amend this specification, including the claims, to expressly recite any sub-range of the same numerical precision subsumed within the ranges expressly recited in this specification. All such ranges are inherently described in this specification such that amending to expressly recite any such sub-ranges will comply with the written description, sufficiency of description, and added matter requirements.

Also, unless expressly specified or otherwise required by context, all numerical parameters described in this specification (such as those expressing values, ranges, amounts, percentages, and the like) may be read as if prefaced by the word “about,” even if the word “about” does not expressly appear before a number. Additionally, numerical parameters described in this specification should be construed in light of the number of reported significant digits, numerical precision, and by applying ordinary rounding techniques. It is also understood that numerical parameters described in this specification will necessarily possess the inherent variability characteristic of the underlying measurement techniques used to determine the numerical value of the parameters.

Notwithstanding that numerical ranges and parameters setting forth the broad scope of the invention are approximations, numerical values set forth in the specific examples are reported precisely as possible. Any numerical value, however, inherently contains certain errors necessarily resulting from the standard variation found in its respective testing measurements.

Reference throughout the specification to “various examples,” “some examples,” “one example,” “an example,” or the like means that a particular feature, structure, or characteristic described in connection with the example is included in an example. Thus, appearances of the phrases “in various examples,” “in some examples,” “in one example,” “in an example,” or the like, in places throughout the specification are not necessarily all referring to the same example. Furthermore, the particular features, structures, or characteristics may be combined in any suitable manner in an example or examples. Thus, the particular features, structures, or characteristics illustrated or described in connection with one example may be combined, in whole or in part, with the features, structures, or characteristics of another example or other examples without limitation. Such modifications and variations are intended to be included within the scope of the present examples.

Any patent, publication, or other document identified in this specification is incorporated by reference into this specification in its entirety unless otherwise indicated but only to the extent that the incorporated material does not conflict with existing descriptions, definitions, statements, illustrations, or other disclosure material expressly set forth in this specification. As such, and to the extent necessary, the express disclosure as set forth in this specification supersedes any conflicting material incorporated by reference. Any material, or portion thereof, that is incorporated by reference into this specification, but which conflicts with existing definitions, statements, or other disclosure material set forth herein, is only incorporated to the extent that no conflict arises between that incorporated material and the existing disclosure material. Applicant reserves the right to amend this specification to expressly recite any subject matter, or portion thereof, incorporated by reference. The amendment of this specification to add such incorporated subject matter will comply with the written description, sufficiency of description, and added matter requirements.

Whereas particular examples of this invention have been described above for purposes of illustration, it will be evident to those skilled in the art that numerous variations of the details of the present invention may be made without departing from the invention as defined in the appended claims.

While the present disclosure provides descriptions of various specific aspects for the purpose of illustrating various aspects of the present disclosure and/or its potential applications, it is understood that variations and modifications will occur to those skilled in the art. Accordingly, the invention or inventions described herein should be understood to be at least as broad as they are claimed and not as more narrowly defined by particular illustrative aspects provided herein.

It is understood that the inventions described in this specification are not limited to the examples summarized in the Summary or Detailed Description. Various other aspects are described and exemplified herein.

1. An integrated circuit assembly comprising:
an integrated circuit die;
an upper layer; and
a thermal interface material disposed in contact with the integrated circuit die and the upper layer, wherein the thermal interface material is between the integrated circuit die and the upper layer, and the thermal interface material comprises:
8% to 70% by volume of a polymer component based on a total volume of the thermal interface material, the polymer component comprising:
5% to 99% by weight of a first polymer comprising a vinyl terminated polydimethylsiloxane based on the total weight of the polymer component, wherein the first polymer has a molecular weight of less than 30,000 g/mol; and
at least one of
5% to 95% by weight of a second polymer comprising a vinyl terminated polydimethylsiloxane based on the total weight of the polymer component, wherein the second polymer has a molecular weight of at least 30,000 g/mol;
1% to 25% by weight of a third polymer comprising an alkyl terminated polydimethylsiloxane based on the total weight of the polymer component, wherein the third polymer has a molecular weight of at least 30,000 g/mol; and
5% to 20% by weight of fourth polymer comprising polybutadiene based on the total weight of the polymer component; and
at least 30% by volume of liquid metal droplets based on total volume of the thermal interface material, wherein the liquid metal droplets are dispersed throughout the polymer component,
wherein the thermal interface material, when cured, has a strain limit of at least 100% and wherein the assembly has a lap shear strength of at least 1 MPa.

2. The assembly of claim 1, wherein the polymer component comprises:
5% to 85% by weight of the first polymer based on the total weight of the polymer component;
5% to 25% by weight of the second polymer based on the total weight of the polymer component;
5% to 10% by weight of the third polymer based on the total weight of the polymer component; and
5% to 20% by weight of fourth polymer comprising polybutadiene based on the total weight of the polymer component.

3. The assembly of claim 1, wherein the polymer component comprises:
40% to 75% by weight of the first polymer based on the total weight of the polymer component;
10% to 25% by weight of the second polymer based on the total weight of the polymer component;
1% to 10% by weight of the third polymer based on the total weight of the polymer component; and
5% to 20% by weight of fourth polymer comprising polybutadiene based on the total weight of the polymer component.

4. The assembly of claim 1, wherein the first polymer has a functionality of at least 3 and the second polymer is difunctional.

5. The assembly of claim 1, wherein the polymer component further comprises one or more of the following:
0.1% to 0.5% by weight of a silane coupling agent based on the total weight of the polymer component;
0.1-0.5% by weight of a fumed silica; and
a catalyst.

6. (canceled)

7. (canceled)

8. The assembly of claim 1, wherein the second polymer comprises a divinyl terminated polydimethylsiloxane.

9. The assembly of claim 1, wherein the third polymer comprises a dialkyl terminated polydimethylsiloxane.

10. The assembly of claim 1, wherein the liquid metal droplets comprise gallium, a gallium alloy, indium, an indium alloy, tin, a tin alloy, mercury, a mercury alloy, or a combination thereof.

11. The assembly of claim 1, wherein the liquid metal droplets are in a liquid phase at least at a temperature in a range of −19 degrees Celsius to 30 degrees Celsius.

12. The assembly of claim 1, wherein the liquid metal droplets are generally ellipsoidal.

13. The assembly of claim 1, wherein a bondline distance formed between the die and the upper layer in the assembly is no greater than 150 microns.

14. The assembly of claim 1, wherein the die comprises a processor and wherein the upper layer comprises a heat sink, an integrated heat spreader, or packaging

15. The assembly of claim 1, wherein the thermal interface material has a 10% Young's modulus of no greater than 3000 kPa.

16. A method comprising:
applying a thermal interface material on an integrated circuit die of an integrated circuit assembly, such that the thermal interface material is between the integrated circuit die and an upper layer of the integrated circuit assembly, wherein the thermal interface material applied to the integrated circuit die comprises:
8% to 70% by volume of a polymer component based on a total weight of the thermal interface material, the polymer component comprising:
5% to 99% by weight of a first polymer comprising a vinyl terminated polydimethylsiloxane based on the total weight of the polymer component, wherein the first polymer has a molecular weight of less than 30,000 g/mol; and
at least one of
5% to 95% by weight of a second polymer comprising a vinyl terminated polydimethylsiloxane based on the total weight of the polymer component, wherein the second polymer has a molecular weight of at least 30,000 g/mol;
1% to 25% by weight of a third polymer comprising an alkyl terminated polydimethylsiloxane based on the total weight of the polymer component, wherein the third polymer has a molecular weight of at least 30,000 g/mol; and
5% to 20% by weight of fourth polymer comprising polybutadiene based on the total weight of the polymer component; and
at least 30% by volume of liquid metal droplets based on total weight of the thermal interface material, wherein the liquid metal droplets are dispersed throughout the polymer component;
wherein the thermal interface material, when cured, has a strain limit of at least 100%;
compressing the integrated circuit assembly thereby deforming the liquid metal droplets, wherein an average particle size of the liquid metal droplets in the thermal interface material prior to applying is greater than a bondline distance formed between the die and the upper layer in a cured assembly formed therefrom; and
curing the thermal interface material thereby forming the cured assembly, wherein the thermal interface material has a lap shear of at least 1 MPa.

17. The method of claim 16, wherein the polymer component comprises:
5% to 90% by weight of the first polymer based on the total weight of the polymer component;
5% to 25% by weight of the second polymer based on the total weight of the polymer component;
5% to 10% by weight of the third polymer based on the total weight of the polymer component; and
5% to 20% by weight of fourth polymer comprising polybutadiene based on the total weight of the polymer component.

18. The method of claim 16, wherein the polymer component comprises:
40% to 75% by weight of the first polymer based on the total weight of the polymer component;
10% to 25% by weight of the second polymer based on the total weight of the polymer component;
1% to 10% by weight of the third polymer based on the total weight of the polymer component; and
5% to 20% by weight of fourth polymer comprising polybutadiene based on the total weight of the polymer component.

19. The method of claim 16, wherein the first polymer has a functionality of at least 3 and the second polymer is difunctional.

20. The method of claim 16, wherein the polymer component further comprises one or more of the following:
0.1% to 0.5% by weight of a silane coupling agent based on the total weight of the polymer component;
0.1-0.5% by weight of a fumed silica; and
a catalyst.

21. (canceled)

22. (canceled)

23. The method of claim 16, wherein the second polymer comprises a divinyl terminated polydimethylsiloxane.

24. The method of claim 16, wherein the third polymer comprises a dialkyl terminated polydimethylsiloxane.

25. The method of claim 16, wherein the liquid metal droplets comprise gallium, a gallium alloy, indium, an indium alloy, tin, a tin alloy, mercury, a mercury alloy, or a combination thereof.

26. The method of claim 16, wherein the liquid metal droplets are in a liquid phase at least at a temperature in a range of −19 degrees Celsius to 30 degrees Celsius.

27. The method of claim 16, wherein the liquid metal droplets are generally ellipsoidal.

28. The method of claim 16, wherein a bondline distance formed between the die and the upper layer in the assembly is no greater than 150 microns.

29. The method of claim 16, wherein the die comprises a processor and wherein the upper layer comprises a heat sink, an integrated heat spreader, or packaging.

30. The method of claim 16, wherein the thermal interface material has a 10% Youngs modulus of no greater than 3000 kPa.

31. An integrated circuit assembly produced by the method of any of claim 16.

32. A thermal interface material comprising:
8% to 70% by volume of a polymer component based on a total volume of the thermal interface material, the polymer component comprising:
5% to 99% by weight of a first polymer comprising a vinyl terminated polydimethylsiloxane based on the total weight of the polymer component, wherein the first polymer has a molecular weight of less than 30,000 g/mol; and
at least one of
5% to 95% by weight of a second polymer comprising a vinyl terminated polydimethylsiloxane based on the total weight of the polymer component, wherein the second polymer has a molecular weight of at least 30,000 g/mol;
1% to 25% by weight of a third polymer comprising an alkyl terminated polydimethylsiloxane based on the total weight of the polymer component, wherein the third polymer has a molecular weight of at least 30,000 g/mol; and
5% to 20% by weight of fourth polymer comprising polybutadiene based on the total weight of the polymer component; and
at least 30% by volume of liquid metal droplets based on total volume of the thermal interface material, wherein the liquid metal droplets are dispersed throughout the polymer component,
wherein the thermal interface material, when cured, has a strain limit of at least 100% and wherein the assembly has a lap shear strength of at least 1 MPa.
